(19) United States
(12) Patent Application Publication
(10) Pub. No.: US 2008/0211060 A1
(43) Pub. Date: Sep. 4, 2008

(54) ANTI-FUSE WHICH WILL NOT GENERATE A NON-LINEAR CURRENT AFTER BEING BLOWN AND OTP MEMORY CELL UTILIZING THE ANTI-FUSE

(76) Inventors: Kuang-Yeh Chang, Hsinchu City (TW); Shing-Ren Sheu, Hsinchu City (TW); Chung-Jen Ho, Tao-Yung County (TW)

Correspondence Address: NORTH AMERICA INTELLECTUAL PROPERTY CORPORATION, P.O. BOX 506, MERRIFIELD, VA, 22116, US

(21) Appl. No.: 11/680,630

(22) Filed: Mar. 1, 2007

(51) Int. Cl. H01L 29/72

(52) U.S. Cl. 257/530; 257/E29.173

(57) ABSTRACT

An anti-fuse is formed with a transistor with a doped channel. The anti-fuse will not generate a non-linear current after the anti-fuse is blown. The anti-fuse is used in memory cells of one-time programmable (OTP) memory. The OTP memory utilizes a p-type transistor and an n-type transistor to program the anti-fuse. The anti-fuse has the doped channel, so a current will not flow through the p/n junction between the substrate and two doped regions of the anti-fuse to form a non-linear current after the anti-fuse is blown. Thus, the memory cells of the OTP memory can be programmed correctly.

### BACKGROUND OF THE INVENTION

1. Field of the Invention

The present invention relates to an anti-fuse, and more particularly, to an anti-fuse without non-linear current after being blown.

2. Description of the Prior Art

An anti-fuse is a short circuit after being blown in contrast with a fuse. In general, the anti-fuse utilizes an insulation layer such as oxides to insulate two ends of the anti-fuse. Before the anti-fuse is blown, the anti-fuse is an open circuit, and a high resistance is between two ends of the anti-fuse. A high voltage is applied to break the insulation layer to blow the anti-fuse. When the anti-fuse is in the situation of the short circuit, a low resistance around 5-25K ohms is between two ends of the anti-fuse, so the anti-fuse is suitable for a programming memory. The programming memory utilizing the anti-fuse, which is a one-time programmable (OTP) memory, can provide good security. The anti-fuse is formed with a complementary metal oxide semiconductor (CMOS) transistor in the prior art, including a p-type transistor or an n-type transistor. The first end of the anti-fuse is the gate of the transistor, and the second end of the anti-fuse is the drain coupled to the source of the transistor, so the gate oxide of the transistor insulates two ends of the anti-fuse. The gate oxide thickness of the transistor for the anti-fuse is smaller than transistors for the operation circuits. When programming the anti-fuse, around 7 volts are applied across two ends of the anti-fuse so as to break the gate oxide of the transistor. Thus, the anti-fuse is blown and forms the short circuit.

Please refer to FIG. 1. FIG. 1 is a diagram of a memory cell 10 of an OTP memory utilizing an n-type anti-fuse according to the prior art. The memory cell 10 of the OTP memory comprises an anti-fuse 12, a p-type transistor 14, and an n-type transistor 16. The anti-fuse 12 is formed with an n-type transistor with the source coupling to the drain. The first end of the anti-fuse 12 is the gate of the n-type transistor, and the second end of the anti-fuse 12 is the short circuit of the source and drain of the n-type transistor. The drain of the p-type transistor 14 and the drain of the n-type transistor 16 are coupled to the first end of the anti-fuse 12, and the second end of the anti-fuse 12 is coupled to a ground GND. A programming voltage VPH is inputted to the source of the p-type transistor 14, and a low voltage VL is inputted to the source of the n-type transistor 16. The p-type transistor 14 and the n-type transistor 16 operate like an inverter. When the memory cell 10 is programmed, the gate of the p-type transistor 14 and the gate of the n-type transistor 16 receive a low level signal, so the p-type transistor 14 turns on and the n-type transistor 16 turns off. The programming voltage VPH is inputted to the first end of the anti-fuse 12 so as to break the oxide of the anti-fuse 12. On the other hand, when the memory cell 10 is not programming, the gate of the p-type transistor 14 and the gate of the n-type transistor 16 receive a high level signal, so the p-type transistor 14 turns off, and the n-type transistor 16 turns on. Thus, the low voltage VL is inputted to the first end of the anti-fuse 12, so the anti-fuse 12 will not be blown.

Please refer to FIG. 2. FIG. 2 is a diagram of a memory cell 20 of an OTP memory utilizing a p-type anti-fuse according to the prior art. The memory cell 20 uses an anti-fuse 18 formed with a p-type transistor. The first end of the anti-fuse 18 is the gate of the p-type transistor, and the second end is a short circuit of the source coupling to the drain of the p-type transistor. The drain of the p-type transistor 14 and the drain of the n-type transistor 16 are coupled to the first end of the anti-fuse 18. The programming voltage VPH is inputted to the second end of the anti-fuse 18, and a high voltage VH is inputted to the source of the p-type transistor 14, and the low voltage VL is inputted to the source of the n-type transistor 16. When the memory cell 20 is programming, the gate of the p-type transistor 14 and the gate of the n-type transistor 16 receive the high level signal, so the p-type transistor 14 turns off and the n-type transistor 16 turns on. A high voltage difference is across two ends of the anti-fuse 18 so as to break the gate oxide of the anti-fuse 18. On the other hand, when the memory cell 20 is not programming, the gate of the p-type transistor 14 and the gate of the n-type transistor 16 receive the low level signal, so the p-type transistor 14 turns on and the n-type transistor 16 turns off. A low voltage difference is across two ends of the anti-fuse 18, so the anti-fuse 18 will not be blown.

Please refer to FIG. 3. FIG. 3 is a cross-sectional diagram of the n-type anti-fuse 12 in FIG. 1. The anti-fuse 12 comprises a p-type substrate 21, two n+ doped regions 22, a dielectric layer 23, a conductive layer 24, an insulation layer 25, and a conductive line 26. The first end of the anti-fuse 12 is the conductive layer 24, and the second end of the anti-fuse 12 is the conductive line 26. The conductive line 26 couples two n+ doped regions 22. When the anti-fuse 12 is programming, the high voltage difference is across two ends of the anti-fuse 12 so as to break the dielectric layer 23. Namely, the programming voltage punches through the dielectric layer 23 and forms a pinhole, so the resistance of the dielectric layer 23 is decreased and the short circuit between the first end and the second of the anti-fuse 12 is formed. The resistance of the anti-fuse 12 is around 5-25K ohms after programming. The pinhole in the dielectric layer 23 formed by the programming voltage VPH may locate near one of the n+ doped regions 22 or between two n+ doped regions 22. When the pinhole locates near one of the n+ doped regions 22, the current can easily flow between the conductive layer 24 and the n+ doped region 22, but when the pinhole locates between two n+ doped regions 22, the current between the conductive layer 24 and the n+ doped region 22 will flow through the p-type substrate 21. However, a p/n junction exists between the n+ doped region 22 and the p-type substrate 21 and generates the non-linear current. The p/n junction of the anti-fuse 12 is like a fuse blown incompletely where the current still can flow through and cause failure. For the OTP memory, the memory cell 10 cannot be detected correctly because of the non-linear current of the anti-fuse 12, and the anti-fuse 18 in FIG. 2 has the similar situation. When the pinhole in the dielectric layer formed by the programming voltage locates between two p+ doped regions, the current between the conductive layer and the p+ doped region will flow through the n-type substrate. The p/n junction also exists between the p+ doped regions and the n-type substrate and generates the non-linear current after the anti-fuse 18 is blown.

In summary, the memory cell of the OTP memory utilizing the anti-fuse formed with the CMOS transistor according to the prior art and can provide good security. The memory cell of the OTP memory comprises the anti-fuse formed with the p-type transistor or the n-type transistor with the short circuit of the source and drain, and the pair of complementary transistors. When the OTP memory is programming, the programming voltage is applied to break the gate oxide of the anti-fuse so as to form the pinhole. However, the pinhole may locate near one of the doped regions or between two doped regions. When the pinhole locates between two n+ doped regions, the current will flow through the p/n junction formed between the doped region and the substrate to form the non-linear current of the anti-fuse. The memory cell of the OTP memory cannot be detected because of the non-linear current of the anti-fuse. Thus, the reliability of the OTP memory is compromised.

### SUMMARY OF THE INVENTION

The present invention provides an anti-fuse without non-linear current after being blown comprising a substrate; a dielectric layer formed on the substrate; a conductive layer formed on the dielectric layer; a first doped region formed in the substrate beneath the conductive layer; two second doped regions formed in the substrate located on two sides of the first doped region and uncovered by the dielectric layer; and a conductive line coupling two second doped regions.

The present invention further provides a memory cell of a one-time programmable memory utilizing an anti-fuse comprising an anti-fuse formed with a transistor with a doped channel, the gate of the transistor as a first end of the anti-fuse, and the source and the drain of the transistor coupled as a second end of the anti-fuse; a p-type transistor, the drain of the p-type transistor coupling to the first end of the anti-fuse; and an n-type transistor, the drain of the n-type transistor coupling to the first end of the anti-fuse.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a memory cell of an OTP memory utilizing an n-type anti-fuse according to the prior art.

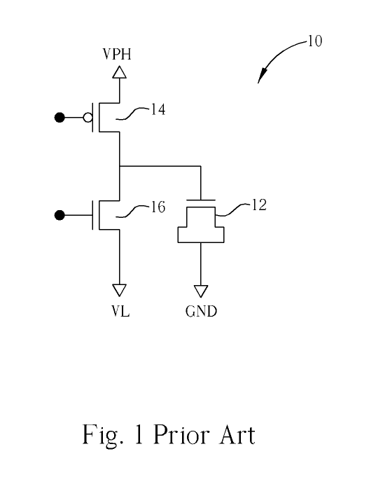

FIG. 2 is a diagram of a memory cell of an OTP memory utilizing a p-type anti-fuse according to the prior art.

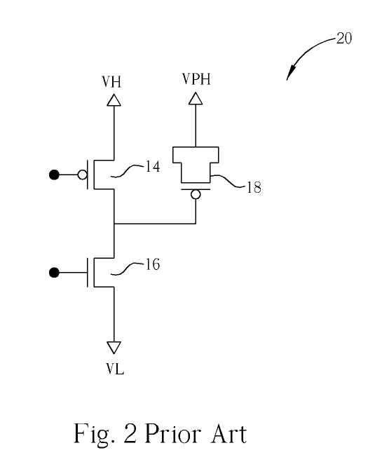

FIG. 3 is a cross-sectional diagram of the n-type anti-fuse in FIG. 1.

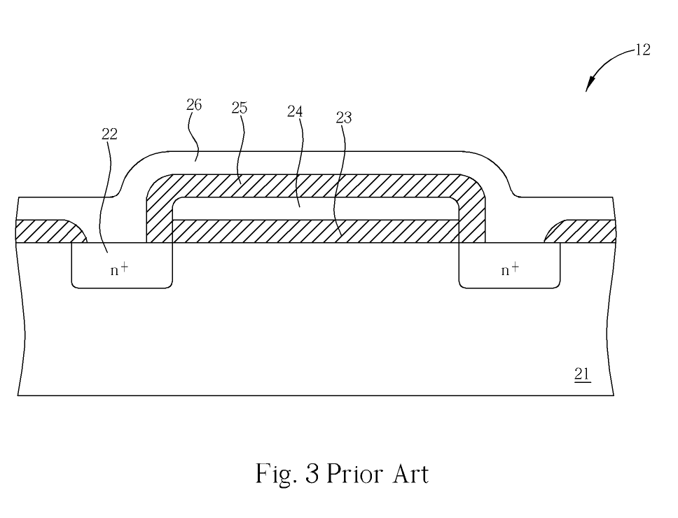

FIG. 4 is a cross-sectional diagram of an anti-fuse of a first embodiment according to the present invention.

FIG. 5 is a cross-sectional diagram of an anti-fuse of a second embodiment according to the present invention.

FIG. 6 is a third embodiment of a memory cell of an OTP memory utilizing the anti-fuse in FIG. 5.

FIG. 7 is a fourth embodiment of a memory cell of an OTP memory utilizing the anti-fuse in FIG. 4.

### DETAILED DESCRIPTION

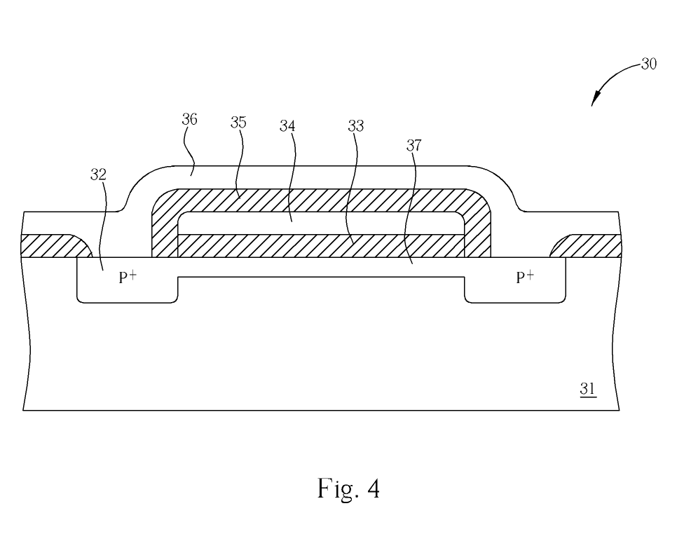

Please refer to FIG. 4. FIG. 4 is a cross-sectional diagram of an anti-fuse 30 of a first embodiment according to the present invention. The anti-fuse 30 comprises an n-type substrate 31, two p+ doped regions 32, a p-type channel 37, a dielectric layer 33, a conductive layer 34, an insulation layer 35, and a conductive line 36. Two p+ doped regions 32 and the p-type channel 37 is embedded from the surface of the n-type substrate 31 and formed in the n-type substrate 31. The dielectric layer 33 is an oxide layer formed on the n-type substrate 31 for insulating the n-type substrate 31 and the conductive layer 34. The conductive layer 34 is a polysilicon layer formed on the dielectric layer 33. The insulation layer 35 is an oxide layer for insulating the conductive layer 34 and the conductive line 36. The conductive line 36 is a metal line coupling two p+ doped regions 32 via contact windows. The first end of the anti-fuse 30 is the conductive layer 34, and the second end of the anti-fuse 30 is the conductive line 36. The conductive line 36 couples two p+ doped regions 32. The p-type channel 37 utilizes p-type carriers of low density to dope between two p+ doped regions 32 by performing the semiconductor processing. The p-type channel 37 is embedded from the surface of the n-type substrate 31 having a depth smaller than two p+ doped regions 32. The p-type channel 37 exists without applied voltages. When the anti-fuse 30 is programming, a programming voltage is inputted to the first end of the anti-fuse 30, so that a high voltage across two ends of the anti-fuse 30 can break the dielectric layer 33. Namely, the programming voltage punches through the dielectric layer 33 and forms a pinhole, so the current can flow through the pinhole of the dielectric layer 33 and a short circuit is formed between the first end and the second end of the anti-fuse 30. The pinhole in the dielectric layer 33 formed by the programming voltage may locate near one of the p+ doped regions 32 or between two p+ doped regions 32. When the pinhole locates near one of the p+ doped regions 32, the current can easily flow between the conductive layer 34 and the p+ doped region 32. When the pinhole locates between two p+ doped regions 32, the current between the conductive layer 34 and the p+ doped region 32 will flow through the p-type channel 37. Thus, no matter where the pinhole locates in the dielectric layer 33, the current can easily flow between the conductive layer 34 and the p+ doped region 32. With p-type channel 37, the anti-fuse 30 will not generate the non-linear current because of the p/n junction between the p+ doped region 32 and the n-type substrate 31.

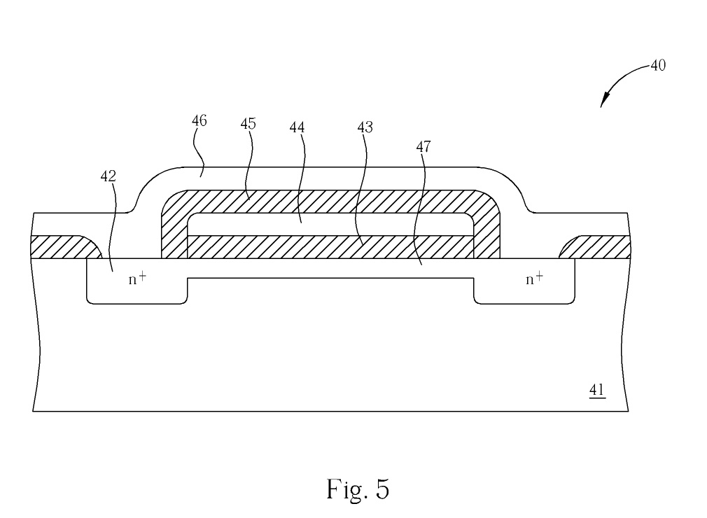

Please refer to FIG. 5. FIG. 5 is a cross-sectional diagram of an anti-fuse 40 of a second embodiment according to the present invention. The anti-fuse 40 comprises a p-type substrate 41, two n+ doped regions 42, an n-type channel 47, a dielectric layer 43, a conductive layer 44, an insulation layer 45, and a conductive line 46. The difference between the first embodiment and the second embodiment is that the anti-fuse 30 of the first embodiment is p-type channel, and the anti-fuse 40 of the second embodiment is n-type channel. The first end of the anti-fuse 40 is the conductive layer 44, and the second end of the anti-fuse 40 is the conductive line 46. The conductive line 46 couples two n+doped regions 42. The n-type channel 47 utilizes n-type carriers of low density to dope between two n+ doped regions 42 by performing the semiconductor processing. The n-type channel 47 is embedded from the surface of the n-type substrate 41 having a depth smaller than two n+ doped regions 42. The n-type channel 47 exists without applied voltages. When the anti-fuse 40 is programming, the programming voltage is inputted to the second end of the anti-fuse 40, so that a high voltage across two ends of the anti-fuse 40 can break the dielectric layer 43. Namely, the programming voltage punches through the dielectric layer 43 and forms a pinhole, so the current can flow through the pinhole of the dielectric layer 43 and a short circuit is formed between the first end and the second end of the anti-fuse 40. Similar to the first embodiment, the pinhole in the dielectric layer 43 formed by the programming voltage may locate near one of the n+ doped regions 42 or between two n+ doped regions 42. Because of the n-type channel 47, no matter where the pinhole locates in the dielectric layer 43, the current can easily flow between the conductive layer 44 and the n+ doped region 42. With n-type channel 47, the anti-fuse 40 will not generate the non-linear current because of the p/n junction between the n+ doped region 42 and the p-type substrate 41. As mentioned in the first embodiment and the second embodiment, the anti-fuse with the doped carrier channel will not generate the non-linear current because of the p/n junction after the anti-fuse is blown.

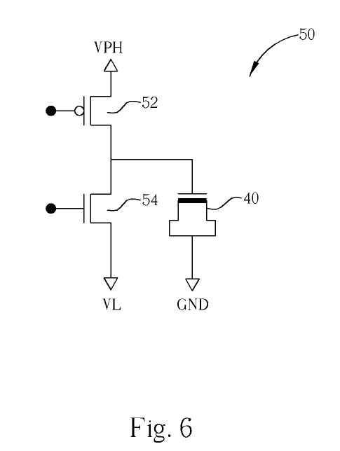

Please refer to FIG. 6. FIG. 6 is a third embodiment of a memory cell 50 of an OTP memory utilizing the anti-fuse 40 in FIG. 5. The memory cell 50 of the OTP memory comprises a p-type transistor 52, an n-type transistor 54, and the anti-fuse 40. The anti-fuse 40 is formed with an n-type transistor with the source coupling to the drain. The first end of the anti-fuse 40 is the gate of the n-type transistor, and the second end of the anti-fuse 40 is the short circuit of the source and the drain of the n-type transistor. The anti-fuse 40 of the n-type transistor has an n-type channel between the source and the drain without applied voltages. In addition, the gate oxide thickness of the anti-fuse 40 is smaller than the p-type transistor 52 and the n-type transistor 54, so the p-type transistor 52 and the n-type transistor 54 can bear higher voltages and current than the anti-fuse 40. The drain of the p-type transistor 52 and the drain of the n-type transistor 54 are coupled to the first end of the anti-fuse 40, and the second end of the anti-fuse 40 is coupled to a ground GND. A programming voltage VPH is inputted to the source of the p-type transistor 52, which is around 4-7 volts, and a low voltage VL is inputted to the source of the n-type transistor 54. The p-type transistor 52 and the n-type transistor 54 operate like an inverter. When the gate of the p-type transistor 52 and the gate of the n-type transistor 54 receive a high level signal, the p-type transistor 52 turns off and the n-type transistor 54 turns on. The first end of the anti-fuse 40 receives the low voltage VL, so the voltage across the anti-fuse 40 is small and the anti-fuse 40 is protected. When the memory cell 50 is programming, the gate of the p-type transistor 52 and the gate of the n-type transistor 54 receive a low level signal, so the p-type transistor 52 turns on and the n-type transistor 54 turns off. The programming voltage VPH is inputted to the first end of the anti-fuse 40 so as to blow the anti-fuse 40. The blowing process of the anti-fuse 40 is the same as the description in the second embodiment. The programming voltage VPH may punch through the pinhole anywhere in the gate oxide of the anti-fuse 40. However, with the n-type channel of the anti-fuse 40, the anti-fuse 40 will not generate the non-linear current because of the p/n junction, so the memory cell 50 can be programmed correctly.

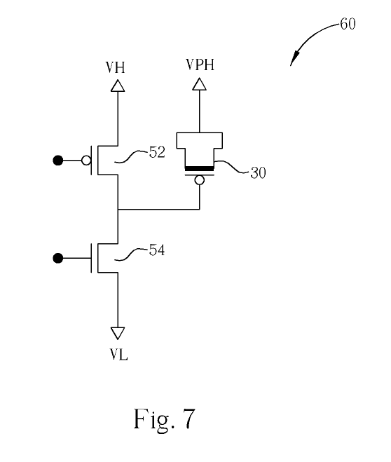

Please refer to FIG. 7. FIG. 7 is a fourth embodiment of a memory cell 60 of an OTP memory utilizing the anti-fuse 30 in FIG. 4. The difference between the fourth embodiment and the third embodiment is that the anti-fuse 30 in the fourth embodiment is formed with a p-type transistor with the source coupling to the drain. The first end of the anti-fuse 30 is the gate of the p-type transistor, and the second end of the anti-fuse 30 is the short circuit of the source and the drain of the p-type transistor. The anti-fuse 30 of the p-type transistor has a p-type channel between the source and the drain without applied voltages. In addition, the gate oxide thickness of the anti-fuse 30 is smaller than the p-type transistor 52 and the n-type transistor 54, so the p-type transistor 52 and the n-type transistor 54 can bear higher voltages and current than the anti-fuse 30. The drain of the p-type transistor 52 and the drain of the n-type transistor 54 are coupled to the first end of the anti-fuse 30, and the programming voltage VPH is inputted to the second end of the anti-fuse 30. A high voltage VH is inputted to the drain of the p-type transistor 52, and the low voltage VL is inputted to the drain of the n-type transistor 54. The p-type transistor 52 and the n-type transistor 54 operate like an inverter. When the gate of the p-type transistor 52 and the gate of the n-type transistor 54 receive the low level signal, the p-type transistor 52 turns on and the n-type transistor 54 turns off. The first end of the anti-fuse 30 receives the high voltage VH, so the voltage across the anti-fuse 30 is small and the anti-fuse 30 is protected. When the memory cell 50 is programming, the gate of the p-type transistor 52 and the gate of the n-type transistor 54 receive the high level signal, so the p-type transistor 52 turns off and the n-type transistor 54 turns on. A high voltage is between two ends of the anti-fuse 30 so as to blow the anti-fuse 30. The blowing process of the anti-fuse 30 is the same as the description in the first embodiment. The programming voltage VPH may punch through the pinhole anywhere in the gate oxide of the anti-fuse 30. However, with the p-type channel of the anti-fuse 30, the anti-fuse 30 will not generate the non-linear current because of the p/n junction, so the memory cell 60 can be programmed correctly. As mentioned in the third embodiment and the fourth embodiment, the memory cell of the OTP memory utilizing the anti-fuse formed with the transistor with the doped carrier channel can be programmed correctly without the influence of the non-linear current cause by the p/n junction, so the reliability of the OTP memory is increased.

In summary, the anti-fuse according to the present invention will not generate the non-linear current after the anti-fuse is blown. The memory cell of the OTP memory utilizes the anti-fuse according to the present invention can increase the reliability. The memory cell of the OTP memory comprises the anti-fuse, the p-type transistor, and the n-type transistor. The anti-fuse is formed with the transistor with the doped channel without applied voltages. The p-type transistor and the n-type transistor operate like an inverter so as to apply the programming to the anti-fuse. The programming voltage may punch through a pinhole at any positions of the gate oxide of the anti-fuse. With the doped channel of the anti-fuse, the current will not flow through the p/n junction after the anti-fuse is blown to form the non-linear current, so the memory cells of the OTP memory can be programmed correctly. Thus, the OTP memory can has a high reliability.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An anti-fuse without non-linear current after being blown comprising:
a substrate;
a dielectric layer formed on the substrate;
a conductive layer formed on the dielectric layer;
a first doped region formed in the substrate beneath the conductive layer;
two second doped regions formed in the substrate located on two sides of the first doped region and uncovered by the dielectric layer; and
a conductive line coupling two second doped regions.

2. The anti-fuse of the claim 1, wherein the first doped region is embedded from the surface of the substrate with a first depth, and the second doped regions are embedded from the surface of the substrate with a second depth larger than the first depth.

3. The anti-fuse of the claim 1, wherein the density of the first doped region is smaller than the second doped regions.

4. The anti-fuse of the claim 1 further comprising an insulation layer covering the surface of the substrate and the conductive layer, wherein the conductive line couples the second doped regions via contact windows.

5. The anti-fuse of the claim 4, wherein the insulation layer is oxide.

6. The anti-fuse of the claim 1, wherein the first doped region is a p-type doped region, and the second doped regions are n-type doped regions, and the substrate is a p-type substrate.

7. The anti-fuse of the claim 1, wherein the first doped region and the second doped regions are p-type doped regions, and the substrate is an n-type substrate.

8. The anti-fuse of the claim 1, wherein the conductive layer is a polysilicon layer.

9. The anti-fuse of the claim 1, wherein the dielectric layer is an oxide layer.

10. The anti-fuse of the claim 1, wherein the conductive line is a metal line.

11. A memory cell of a one-time programmable memory utilizing an anti-fuse comprising:
an anti-fuse formed with a transistor with a doped channel, the gate of the transistor as a first end of the anti-fuse, and the source of the transistor coupling to the drain of the transistor as a second end of the anti-fuse;
a p-type transistor, the drain of the p-type transistor coupling to the first end of the anti-fuse; and
an n-type transistor, the drain of the n-type transistor coupling to the first end of the anti-fuse.

12. The memory cell of the claim 11, wherein the anti-fuse, the p-type transistor, and the n-type transistor are complementary metal oxide semiconductor transistors.

13. The memory cell of the claim 1 1, wherein the transistor with the doped channel is a transistor with a p-type doped channel.

14. The memory cell of the claim 13, wherein the second end of the anti-fuse couples to a high voltage end.

15. The memory cell of the claim 1 1, wherein the transistor with the doped channel is a transistor with an n-type doped channel.

16. The memory cell of the claim 15, wherein the second end of the anti-fuse couples to a ground.
